(19) United States
(12) Patent Application Publication
(10) Pub. No.: US 2008/0078503 A1
(43) Pub. Date: Apr. 3, 2008

(54) Mechanical pump operating well for a long term and method of manufacturing the same

(75) Inventors: Tadahiro OHMI, Miyagi (JP); Isao Akutsu, Ibaraki (JP)

Correspondence Address: FOLEY AND LARDNER LLP;SUITE 500, 3000 K STREET NW, WASHINGTON, DC, 20007, US

(73) Assignees: National University Corporation Tohoku University; Foundation for Advancement of International Science

(21) Appl. No.: 11/905,580

(22) Filed: Oct. 2, 2007

(30) Foreign Application Priority Data
Oct. 3, 2006 (JP) 2006-271816

(51) Int. Cl. H01L 21/00; B05D 3/00; C30B 35/00; F04B 53/00

(52) U.S. Cl. 156/345.1; 117/200; 417/32; 427/372.2

(57) ABSTRACT

A mechanical pump of the present invention is applied to, for example, a screw pump A for exhausting a gas from a processing chamber. The screw pump comprises a gas-exposed region exposed to the gas and an yttria (Y₂O₃) film formed on the gas-exposed region.

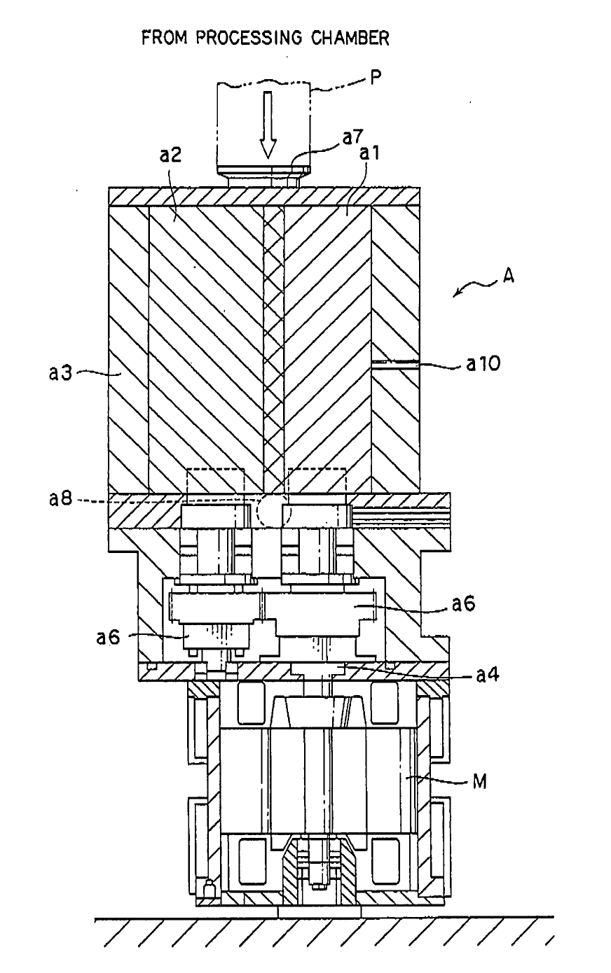

This application is based on and claims the benefit of priority from Japanese patent application No. 2006-271816, filed on Oct. 3, 2006, the disclosure of which is incorporated herein in its entirety by reference.

### BACKGROUND OF THE INVENTION

This invention relates to a mechanical pump and, in particular, relates to a mechanical pump for exhausting a gas from a processing chamber included in an apparatus such as a semiconductor manufacturing apparatus, a thin-shaped display manufacturing apparatus for such as a liquid crystal display, and a photovoltaic cell manufacturing apparatus and to a method of manufacturing the pump.

As one of the kind of mechanical pump for exhausting a gas, a screw pump is known. The screw pump comprises a pair of screw rotors, a casing which contains the screw rotors, inlet and outlet ports formed on the casing. Each of the screw rotors is provided with a pair of helical thread and helical root. The screw rotors are engaged with each other and respectively rotate about rotation axes which are substantially parallel to each other. Generally, on a gas-exposed region in the mechanical pump which is exposed to gas or fluid to be exhausted by the mechanical pump, a surface-treatment of nickel series is applied.

For example, the kind of mechanical pump is disclosed in Japanese Unexamined Patent Application Publication (JP-A) No. H10-141263. Also, Japanese Unexamined Patent Application Publication (JP-A) No. 2004-278308 discloses vacuum pumps including the mechanical pump mentioned above.

During a processing step of a plasma etching or a vapor phase epitaxy, the mechanical pump used in such as the semiconductor manufacturing apparatus, the thin-shaped display manufacturing apparatus, and the photovoltaic cell manufacturing apparatus decompresses an interior of a process chamber. In such a processing step, a gas required for processing is introduced in the decompressed process chamber as a processing gas. For example, such a gas includes hydrogen compound molecules such as SiH₄, AsH₃, PH₃, or B₂H₆. Such a gas is toxic and/or corrosive in many cases and should be exhausted from the process chamber after the processing step. When the gas is exhausted from the process chamber by the mechanical pump, the gas corrodes the gas-exposed region of the mechanical pump. Furthermore, the gases are dissociated (decomposed) by a catalyst action of nickel formed and presented on the gas-exposed region and thus Si, As, P, B, or the like is produced as reactive product. The reactive products are accumulated on the gas-exposed region and thus impeding smooth operation of the mechanical pump.

### SUMMARY OF THE INVENTION

It is therefore an object of this invention to provide a mechanical pump which prevents the reactive products caused by the gas to be exhausted corroding the gas-exposed region and accumulating on the gas-exposed region, and also which operates well for a long time, and a method of manufacturing the same.

It is another object of this invention to provide a semiconductor manufacturing apparatus, a thin-shaped display manufacturing apparatus, and a photovoltaic cell manufacturing apparatus each of which comprises the above-mentioned mechanical pump.

Other objects and advantages of this invention will become clear as the description proceeds.

According to an aspect of this invention, there is provided a mechanical pump for exhausting a gas. The mechanical pump comprises a gas-exposed region exposed to the gas and an yttria film formed on the gas-exposed region.

According to another aspect of this invention, there is provided a method of manufacturing the above-mentioned mechanical pump comprising the step of forming the yttria film by a sol-gel process.

### BRIEF DESCRIPTION OF THE DRAWINGS

A sole FIGURE is a sectional view showing a screw pump according to an embodiment of this invention.

### DESCRIPTION OF THE PREFERRED EMBODIMENT

Hereinbelow, a mechanical pump according to an embodiment of this invention will be described in detail with reference to the drawing.

The mechanical pump of the embodiment comprises an inner surface, in particular, a gas exposed region exposed to gas (processing gas) to be exhausted. On the gas-exposed region, an yttria (yttrium oxide (Y₂O₃)) film is formed.

The yttria (Y₂O₃) is excellent in corrosion resistance and does not have the catalyst action such as nickel. Consequently, the dissociation of gas to be exhausted is suppressed and therefore the accumulation of the reactive products on the gas-exposed region is also suppressed. Thus, the mechanical pump is excellent in durability and can operate well for a long time.

A sole FIGURE is a cross sectional view of a screw pump A as the mechanical pump of the embodiment.

Referring to the FIGURE, the screw pump A comprises a pair of screw rotors a1 and a2. Each of the screw rotors a1 and a2 is provided with a pair of helical thread and helical root. The screw rotors a1 and a2 are engaged with each other and respectively rotate about rotation axes which are substantially parallel to each other.

The screw rotors a1 and a2 are contained in a casing a3 and are supported so as to rotate. To lower ends of the screw rotors a1 and a2, timing gears a6 are connected, respectively. The timing gears a6 are engaged with each other. One of the timing gears a6 is connected to a motor M through a shaft a4. Thus, the screw rotors a1 and a2 are driven by the motor M through the shaft a4 and the timing gears a6 and rotate in sync with each other.

An inlet port a7 is formed on an upper end of the casing a3 while an outlet port a8 is formed on a lower end of the casing a3. When the screw rotors a1 and a2 rotate in sync with each other, a gas (processing gas) is sucked through the inlet port a7 and is exhausted out through the outlet port a8.

As the gas-exposed region of the screw pump A, which is exposed to the gas to be exhausted, there are an inner surface of the casing a3, each surface of the screw rotors a1 and a2, and each inner surface of the inlet and the outlet ports a7 and a8. On the gas-exposed region of the screw pump A, the yttria film which is in a range of 0.1 to 10 μm in thickness is formed.

For example, the yttria film is formed by a sol-gel process. In the embodiment, the yttria film is formed on the gas-exposed region of the screw pump A as follows.

On the gas-exposed region of the screw pump A which has been assembled, an yttria (Y₂O₃) sol is applied. The yttria sol is a kind of colloid solution in which colloidal yttria is dispersed in an organic solvent.

After applying the yttria sol, the screw pump A is heat-treated in a range of 250 to 1000° C. under nitrogen and oxygen atmosphere in which a ratio of nitrogen to oxygen is 80 to 20 for example or under reduced pressure. It is more preferred that the temperature of the heat treatment is in a range of 800 to 900° C.

The yttria sol turns into gel and an yttria gel adheres to the gas-exposed region as the yttria film. Thus, the yttria film is formed on the gas-exposed region of the screw pump A.

However, the yttria film may be previously formed on each gas-exposed region of components to be assembled into the screw pump A such as the casing a3 and the screw rotors a1 and a2.

The screw pump A is used for exhausting gas from a processing chamber included in a semiconductor manufacturing apparatus, a thin-shaped display, such as a liquid crystal display, manufacturing apparatus, or a photovoltaic cell manufacturing apparatus. It is preferred that a passivation film such as the yttria film is formed on an inner surface of each processing chamber of these apparatuses and inner surface of a piping P connected between the processing chamber and the inlet port a7 of the screw pump A.

In order to more surely prevent the reactive products being accumulated on the gas-exposed region, it is preferred to maintain the gas-exposed region in 80° C. or more. This is because the reactive products are hard to be accumulated on the gas-exposed region when the gas-exposed region is maintained in 80° C. or more. While, in order to protect the mechanical pump A from trouble, it is preferred to maintain the mechanical pump A including the gas-exposed region in 250° C. or less. Therefore, it is preferred to maintain the gas-exposed region of the screw pump A within a range of 80 to 250° C. It is more preferred to maintain the gas-exposed region in 150° C.

The screw pump A comprises a temperature control means for maintaining the gas-exposed region within a range of 80 to 250° C. or in 150° C. The temperature control means includes an electric heater as a heating means for heating the gas-exposed region, a cooling system for cooling the gas-exposed region, a controller, and temperature sensors arranged in or on predetermined points of the screw pump A (all of which are not shown).

For example, the heating means is structured by an electric heater. However, the heating means may be a means which uses heat caused by the operation of the screw pump A. For example, the heat is compression heat caused by the operation of the screw pump A and/or frictional heat caused by the motion of a movable member of the screw pump A. The cooling system is, for example, structured by that refrigerant fluid such as water, oil, or air flows through a hollow pathway formed in or on the casing a3.

The controller carries out a feedback control based on the temperatures of the screw pump A sensed by the temperature sensors so that the temperature of the gas-exposed region is maintained in the above-mentioned temperature by using the electric heater and the cooling system.

Furthermore, a gas inlet a10 for inletting inert gas is formed on the casing a3 of the screw pump A. The inert gas inlet through the gas inlet a10 flows between the screw rotors a1 and a2 and attenuates gas presented between the screw rotors a1 and a2. Consequently, even when the gas is low molecular mass, the exhaust of the gas is accelerated. In addition, corrosion of the gas-exposed region and occurrence of the reactive products are suppressed.

Although this invention has been described in conjunction with a preferred embodiment thereof, this invention may be modified in various other manners within the scope of this invention. For example, this invention is applicable not only to the screw pump but also to any mechanical pump such as a roots pump. Also, the mechanical pump according to this invention is applicable not only to the semiconductor manufacturing apparatus, the thin-shaped display manufacturing apparatus, or the photovoltaic cell manufacturing apparatus but also to any apparatus comprising a processing chamber which requires exhaust. Furthermore, the object to be exhausted by the mechanical pump according to this invention is not only gas but also the overall fluid such as liquid.

What is claimed is:

1. A mechanical pump for exhausting a gas and comprising a gas-exposed region exposed to the gas and an yttria film formed on said gas-exposed region.

2. The mechanical pump according to claim 1, wherein the thickness of said yttria film is in a range of 0.1 to 10 μm.

3. The mechanical pump according to claim 1, wherein said pump further comprises a temperature control means which maintains the temperature of said gas-exposed region within a range of 80 to 250° C.

4. The mechanical pump according to claim 3, wherein said temperature control means includes a heating means for heating said gas-exposed region.

5. The mechanical pump according to claim 3, wherein said temperature control means uses compression heat caused by the operation of said pump and/or frictional heat caused by the motion of a movable member.

6. A semiconductor manufacturing apparatus comprising said mechanical pump according to claim 1, a processing chamber in which a process is performed with the use of a gas and in which the gas is exhausted by said mechanical pump, and a piping connecting between said processing chamber and said mechanical pump;
said apparatus further comprising a passivation film formed on an inner surface of at least one of said processing chamber and said piping.

7. A thin-shaped display manufacturing apparatus comprising said mechanical pump according to claim 1, a processing chamber in which a process is performed with the use of a gas and in which the gas is exhausted by said mechanical pump, and a piping connecting between said processing chamber and said mechanical pump;
said apparatus further comprising a passivation film formed on an inner surface of at least one of said processing chamber and said piping.

8. A photovoltaic cell manufacturing apparatus comprising said mechanical pump according to claim 1, a processing chamber in which a process is performed with the use of a gas and in which the gas is exhausted by said mechanical pump, and a piping connecting between said processing chamber and said mechanical pump;
said apparatus further comprising a passivation film formed on an inner surface of at least one of said processing chamber and said piping.

9. A method of manufacturing said mechanical pump according to claim 1, the method comprising a step of forming said yttria film by a sol-gel process.

10. The method according to claim 9, wherein the sol-gel process involves a heat treating in a range of 250 to 1000° C.
